(19) United States
(12) Patent Application Publication
(10) Pub. No.: US 2020/0010989 A1
(43) Pub. Date: Jan. 9, 2020

(54) Composite Membrane and Method for Manufacturing Such a Membrane

(71) Applicants: Sorbonne Université, PARIS (FR); Centre National de la Recherche Scientifique, PARIS (FR)

(72) Inventors: Arnaud ANTKOWIAK, GENTILLY (FR); Paul GRANDGEORGE, IVRY-SUR-SEINE (FR); Natacha KRINS, PARIS (FR); Christel LABERTY-ROBERT, PARIS (FR)

(21) Appl. No.: 16/492,920

(22) PCT Filed: Mar. 9, 2018
(86) PCT No.: PCT/FR2018/050557

§ 371 Date: Sep. 10, 2019

(30) Foreign Application Priority Data
Mar. 10, 2017 (FR) 1751950

(51) Int. Cl. D04H 1/728; D01D 5/00; H05K 1/02; H05K 1/03

(52) U.S. Cl. CPC D04H 1/728; D01D 5/0038; H05K 2201/026; H05K 1/038; H05K 1/0283

(57) ABSTRACT

The present invention relates to a composite membrane (10) comprising a fibrous fabric (1) of nanofibres (11), wherein the thickness of the fabric (1) is between 10 nm and 50 μm and said fabric is impregnated with a wetting liquid (A). According to the invention, the composite membrane is immersed in a second fluid (B) which is immiscible with the wetting liquid (A), forming an A/B interface between the wetting liquid (A) and the immiscible fluid (B), and the composite membrane is capable of remaining tensioned when it is compressed from its resting state until reaching dimensions corresponding to 5% of its dimensions in the resting state, and when it is stretched from its compressed state until reaching dimensions corresponding to 2000% of the length in the compressed state. The present invention also relates to a process for manufacturing such a membrane.

The present invention relates in general to a composite membrane comprising a fibrous fabric impregnated with a liquid wetting it. The present invention also relates to the production of such a membrane.

It is known to those skilled in the art that composite materials make it possible to cover a vast range of mechanical, thermal and optical properties which cannot be produced with a single type of material. In the context of composite materials combining several materials in the solid state, mention may in particular be made of reinforced concrete, which has the high compressive strength of concrete, but also a tensile strength by virtue of the metal rods structuring the reinforced concrete (thus constituting its reinforcement).

Other composite materials can combine a liquid phase and a solid phase in order to take advantage of their respective properties. A hollow tube filled with a small amount of liquid (oil for example) will provide excellent thermal conductivity without electrical conductivity, the tube ensuring the structural integrity of this composite material. No simple solid material can achieve this type of performance.

In addition to the combination of these two phases of different natures, solid-liquid interactions can also considerably affect the mechanical properties of a composite material. For example, spider silk consists of fibers of filamentous proteins composed of hydrophilic and hydrophobic block copolymers and water, which become even more wet when the hygrometry is high (typically greater than 70%) or when the silk is suddenly wetted. By virtue of the elasto-capillary coiling of the fibers, spider capture silk shows an unexpected liquid behavior in compression (it remains tensioned all along the shortening of its end-to-end length), but remains solid in extension (then showing an elastic behavior).

The applicant has used the behavior of this one-dimensional solid-liquid object constituted by capillary spider silk as inspiration to develop a two-dimensional solid-liquid composite membrane having the same property as capillary spider silk.

More particularly, the applicant has developed a composite membrane comprising a fibrous fabric of nanofibers, the thickness of the fabric being between 10 nm and 50 km, the fabric being impregnated with a wetting liquid A.

According to the invention, the composite membrane is immersed in a second fluid B which is immiscible with the wetting liquid A, forming an A/B interface between the wetting liquid A and said immiscible fluid B, and the composite membrane is capable of remaining tensioned:
when it is compressed from its resting state, until reaching dimensions corresponding to 5% of its dimensions in the resting state, and
when it is stretched from its compressed state until reaching dimensions corresponding to 2000% of the length in the compressed state.

For the purposes of the present invention, the term “composite membrane” is intended to mean a membrane comprising a solid reinforcement (or fabric) and a liquid impregnating the reinforcement while wetting it.

For the purposes of the present invention, the term “tensioned membrane” is intended to mean a membrane which is in a state of mechanical tension.

For the purposes of the present invention, the term “miscible fluids” is intended to mean fluids A and B which form only a single phase and there is no surface tension at the A/B interface. Conversely, when fluids A and B are not miscible, they form two distinct phases, with a non-zero surface tension at the A/B interface.

In the fibrous fabric of the membrane according to the invention, the nanofibers are arranged in the form of a mat comprising between 1 and 20 layers of nanofibers.

For the purposes of the present invention, the term “nanofibers” is intended to mean fibers having a diameter of between 10 nm and 5 μm, and typically of about 200 nm.

For the purposes of the present invention, the term “liquid which wets the tissue” is intended to mean a liquid which exhibits an angle of contact of less than 90° with a flat surface of the material making up the nanofibers of the fabric.

Advantageously, the A/B interface formed by the wetting liquid A and the immiscible fluid B can be an oil/air interface, an oil/water interface, or a glycerol/air interface, or an interface of water with surfactant/air. The A/B interface is stable over time (that is to say over the period of time in which the composite membrane is used) since the liquid A which impregnates the fibrous mat does not diffuse into the fluid B. The A/B interface is present on both sides of the composite membrane.

For the purposes of the present invention, the term “surfactant” (or “detergent”) is intended to mean a substance which, even used in a low amount, significantly modifies the surface tension of the fluid containing it, for example of water when the detergent used is dissolved soap. In this case, if the composite membrane according to the invention impregnated with soapy water is brought into contact with air, the A/B interface is an interface of soapy water/air type.

The composite membrane according to the invention can adjust its surface and its shape so as to always remain under tension regardless of the nature of the mechanical stress to which it is subjected, in the same way as a simple soapy liquid film, without ever breaking, by virtue of its solid nature. For that, the fibrous mat folds spontaneously within the liquid layer with which it is soaked when the edges of the composite membrane are moved closer together. The surface tension developed by the A/B interface allows the membrane to remain tensioned even when it is compressed, as opposed to a dry membrane which would sag under its weight. In other words, the membrane according to the invention has the property of remaining in a tensioned state regardless of the nature of the mechanical stress of the membrane:
on the one hand, when it is compressed, from its resting state, at a compression ratio which can range up to 5% of its dimensions in the resting state (that is to say that the membrane is in a state which is not mechanically pre-stretched or pre-stressed), the membrane operates like a liquid film;
on the other hand, when it is stretched, from its compressed state, at a degree of stretching which can range up to 2000% of the length in the compressed state, the membrane operates like a liquid film at the beginning, then like a solid film.

For the purposes of the present invention, the term “compression ratio” is intended to mean the ratio between the distance between the ends of a characteristic dimension of the fabric, under the effect of a compressive mechanical strain, and this distance in the resting state.

The thickness of the fabric can be advantageously between 500 nm and 30 μm, and preferably between 1 μm and 5 μm.

The nanofibers of the fabric can advantageously have a diameter between 100 nm and 500 nm, and preferably of about 200 nm.

Thus, it can be used in multiple applications, and in particular as artificial muscle, or for constituting a stretchable electronic circuit, or also as a smart power circuit, or also as a SLIPS (“Slippery Liquid-Infused Porous Surfaces”) membrane.

For the purposes of the present invention, the term “artificial muscle” is intended to mean an organ capable of developing a mechanical force in reaction to an exterior stimulus.

For the purposes of the present invention, the term “smart power circuit” is intended to mean a circuit of which the electrical behavior depends on the mechanical strain imposed on the membrane.

For the purposes of the present invention, the term “SLIPS membrane” is intended to mean a membrane impregnated with a wetting liquid A. When brought into contact with an immiscible liquid B, the surface of the membrane impregnated with the liquid A is slippery for the liquid B.

A subject of the present invention is also a process for manufacturing a composite membrane according to the invention by electrically assisted extrusion, comprising the following steps:
A. Forming a solution, in a solvent medium, of a material capable of being dissolved by said solvent medium;
B. injecting said solution at a flow rate Q into a capillary tube having a diameter d_{c} subjected to an electrical voltage U of between 1 kV and 100 kV, and preferably between 10 kV and 30 kV, the diameter d_{c} being between 0.5 mm and 2 mm, and preferably about 1 mm;
C. forming, at the outlet of the capillary tube, a drop of said solution, said drop being electrically charged so as to bring about its destabilization in the form of a “Taylor” cone^{[1],[2]};
D. ejecting, from said cone, a liquid cylinder toward an electrically conductive target, which is electrically earthed;
E. evaporating said solvent during the ejecting of the liquid cylinder, resulting in a vortex instability generating solid nanofibers of the material;
F. collecting, on one face of said target oriented toward said cylinder, solid nanofibers so as to form a mat of nanofibers forming a fibrous fabric, said target being, prior to step B, covered with a non-stick coating;

said process being characterized in that it also comprises, at the end of step F, an additional step G of wetting the fibrous fabric with a wetting liquid A, so as to form a wetted membrane; and

in that it comprises a step of immersing the wetted membrane thus obtained in a fluid B which is immiscible with the wetting liquid A, so as to create an A/B interface between the wetting liquid A and the immiscible fluid B and thus to form the composite membrane according to the invention.

The composite membrane, the fibrous fabric and the nanofibers, which constitute it, the wetting liquid A and the fluid B which is immiscible with the liquid A (and consequently the A/B interface) are as defined above.

Thus, the A/B interface obtained following the immersion of the wetted membrane in the fluid B may advantageously be an oil/air interface, an oil/water interface, or a glycerol/air interface, or an interface of water with surfactant or detergent/air, for example of the soapy water type.

For the purposes of the present invention, the term “material” is intended to mean the matter constituting the nanofibers of the fibrous fabric.

Advantageously, a parchment paper, for example the parchment paper sold by the store Monoprix® under the trade name PAPIER CUISSON 8 METRES, is used as non-stick coating.

Advantageously, the surface of the target which is oriented toward the cylinder is a flat face located at a distance L from the outlet (3a) of the capillary tube (3) of between 5 cm and 15 cm, the capillary tube being subjected to an electrical voltage U of between 10 kV and 15 kV.

Preferably, this flat surface of the target is located at a distance L from the outlet (3a) of the capillary tube (3) which is about 10 cm, the capillary tube being subjected to an electrical voltage U of about 12 kV.

Advantageously, the constituent material of the fabric may be a polymer material chosen from the group consisting of the following polymers:
polyacrylonitrile (PAN),
polyvinylidene fluoride-co-hexafluoropropylene (PVDF-HFP),
polyvinylpyrrolidone (PVP),
polyvinyl alcohol (PVA),
polyethylene oxide (PEO), and
polyvinylidene fluoride (PVDF).

In addition to the abovementioned polymer materials, a polymer-inorganic network hybrid material, wherein the inorganic network may be, for example, SiO₂ (silica), TiO₂ (titanium dioxide), Fe₂O₃(iron oxide), in the form of an amorphous network or of crystallized nanoparticles, may also be advantageous.

Other advantages and particularities of the present invention will result from the following description, given by way of nonlimiting example and produced with reference to the examples and to the appended figures:

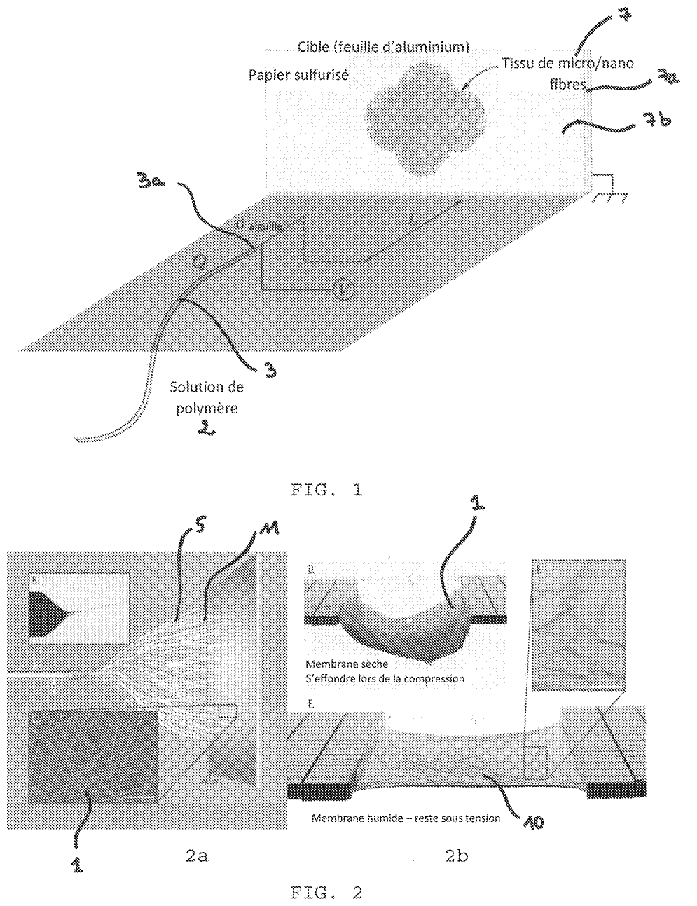

FIG. 1 represents a schematic view from a side-on perspective of an electrically assisted extrusion device for carrying out the process according to the invention;

FIGS. 2A and 2B schematically represents the formation of the “Taylor” cone at the outlet of the capillary tube of the device of FIG. 1 (cf.

FIG. 2A) and the behavior in compression and in extension of the composite membrane according to the invention obtained at the end of the implementation of the process according to the invention using the device of FIG. 1 (cf. FIG. 2B);

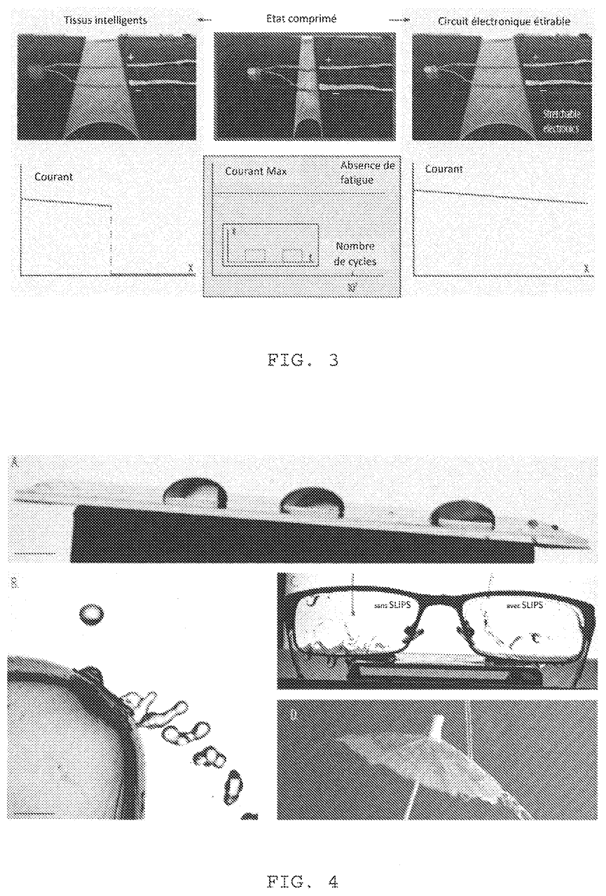

FIG. 3 shows the use of the composite membrane according to the invention as a smart power circuit;

FIG. 4 shows the use of the composite membrane according to the invention as a SLIPS membrane.

The technical characteristics common to these figures are each denoted by the same numerical reference in the figures in question.

Schematically represented in FIGS. 1, 2A, and 2B, from a side-on perspective, is an electrically assisted extrusion device for carrying out the process according to the invention. This device is operated as follows:
introduced into a solvent medium is a material capable of being dissolved by this solvent medium; in the case of a polymer material, a polymer solution 2 is formed;
this solution 2 is then injected, at a flow rate Q, into a capillary tube 3 subjected to an electrical voltage U of between 1 kV and 100 kV (cf. FIG. 1 and photograph A of FIG. 2A);
the formation of a drop 4 of solution 2 is observed at the outlet 3a of the capillary tube 3 (cf. photographs A and B of FIG. 2A);
this drop 4 is electrically charged, which brings about its destabilization in the form of a cone 5 (cf. photo B of FIG. 2A);
then, a liquid cylinder 6 (cf. photograph B of FIG. 2A) is continuously ejected from the cone 5 toward an electrically conductive target 7 (visible in FIG. 1 and FIGS. 2A and 2B), which is electrically earthed;
during the ejection of the liquid cylinder 6, the solvent evaporates, which results in a vortex instability generating solid nanofibers of the material (cf. photograph A of FIG. 2A) at a flow rate consisting of thousands of nanofibers per second, resulting in the formation of a mat of nanofibers constituting the fibrous fabric 1 (cf. photo C of FIG. 2A);
then, the fibrous fabric 1 is collected on a face 7a of the target 7 oriented toward the cylinder 6, the face 7a of the target 7 being previously covered with a non-stick coating 7b such as parchment paper;
then, the fibrous fabric 1 thus obtained is wetted (cf. photograph D of FIG. 2B) with a wetting liquid A (in this case water), so as to form a wetted membrane;
finally, the wetted membrane thus obtained is immersed in a fluid B (in this case air), which is immiscible with the wetting liquid A, so as to create an A/B interface between the wetting liquid (A) and said immiscible fluid (B). A composite membrane 10 according to the invention is obtained (cf. photograph E of FIG. 2B).

FIGS. 1, 2A, and 2B show that the face 7a of the target 7 on which the nanofibers/fibrous fabric are collected is a flat face. However, it is possible to use a target which is not flat, for example in the shape of a sphere.

Photograph D of FIG. 2B is a photograph showing the behavior in compression of the non-wetted fibrous fabric: bending/buckling of the fabric in compression is observed.

Photograph E of FIG. 2B shows the behavior in compression of the composite membrane 10 according to the invention: it is observed that, once wetted, the membrane undergoes self-tensioning under the action of a capillary voltage. This self-tensioning is reminiscent to that of a conventional film of soap on a frame.

On photographs D and E of FIG. 2B, X₀ corresponds to the distance between the two ends of the membrane (X₀=6 cm for the two images).

Photograph F of FIG. 2B is a detailed view of a part of the composite membrane according to the invention, showing an excess of wrinkles inside the liquid film.

FIG. 3 shows the use of the composite membrane according to the invention as a smart power circuit, and also as a stretchable electronic circuit. In particular, this figure shows that the electrical response of a smart fabric depends on its state of extension, whereas a stretchable electronic circuit refers to an extendable fabric which can transport electronic information in any state of extension. For such uses, the composite membrane according to the invention does not undergo fatigue and, consequently, electronic information can be produced through numerous compression cycles.

FIG. 4 shows the use of the composite membrane according to the invention as a SLIPS membrane. This figure shows in particular that these membranes are interchangeable, replaceable and adaptable to several surfaces. Thus, a SLIPS membrane according to the invention made of PVDF-HFP (fabric) with an A/B interface of silicone oil/air or silicone oil/water type can be attached to any type of surface; it will adapt to its shape in order to closely cover it. It gives excellent results for self-cleaning surfaces:
in photograph A, the SLIPS membrane according to the invention is placed on a self-cleaning surface: a droplet of water falling onto the glass does not attach thereto. By virtue of the SLIPS coating, it begins to slide starting from a relatively small contact angle, of about 40 (scale bar: 0.5 cm);
in photograph B, the SLIPS membrane according to the invention is placed on a hydrophobic surface. By virtue of this SLIPS treatment, the drop falls back on the surface without leaving traces (scale bar 1 cm);
in photograph C, the SLIPS membrane according to the invention is placed on a hemisphere of glass treated with this SLIPS membrane according to the invention; the droplets of water slide over the SLIPS coating, whereas they remain trapped on a non-treated normal glass.
The same is true for paper cocktail umbrellas represented in photograph D: the droplets of water slide if a SLIPS membrane according to the invention has been placed on the umbrella.

### LIST OF REFERENCES

[1] G. Taylor. “Disintegration of water drops in an electric field.” Proceedings of the Royal Society of London. Series A, Mathematical and Physical Sciences, 280(1382):383-397, 1964.
[2] M. S. Wilm and M. Mann. “Electrospray and Taylor-Cone theory, Dole's beam of macromolecules at last.” International Journal of Mass Spectrometry and Ion Processes 136.2-3 (1994): 167-180.

1. A composite membrane comprising a fibrous fabric of nanofibers, the thickness of the fabric being between 10 nm and 50 μm, said fabric being impregnated with a wetting liquid, said composite membrane being characterized:
in that it is immersed in a second fluid which is immiscible with the wetting liquid, forming an A/B interface between the wetting liquid and said immiscible fluid, and
in that it is capable of remaining tensioned:
when it is compressed from its resting state, until reaching dimensions corresponding to 5% of its dimensions in the resting state, and
when it is stretched from its compressed state until reaching dimensions corresponding to 2000% of the length of the compressed state.

2. The composite membrane as claimed in claim 1, wherein the thickness of said fibrous fabric is between 500 nm and 30 μm, and preferably between 1 μm and 5 μm.

3. The composite membrane as claimed in claim 2, wherein said nanofibers of the fibrous fabric have a diameter of between 100 nm and 500 nm, and preferably of about 200 nm.

4. The hybrid membrane as claimed in claim 1, wherein said A/B interface is an oil/air interface, an oil/water interface, or a glycerol/air interface, or an interface of water with surfactant/air.

5. The use of the membrane as defined in claim 1, as an organ capable of developing a mechanical force in reaction to an exterior stimulus, typically an artificial muscle.

6. The use of the membrane as defined in claim 1, for constituting a stretchable electronic circuit.

7. The use of the membrane as defined in claim 1, as a smart power circuit.

8. The use of the membrane as defined in claim 1, as a SLIPS membrane.

9. A process for manufacturing a composite membrane as defined in claim 1, comprising the following steps:
A. forming a solution, in a solvent medium, of a material capable of being dissolved by said solvent medium;
B. injecting said solution at a flow rate Q into a capillary tube having a diameter do subjected to an electrical voltage U of between 1 kV and 100 kV, the diameter do being between 0.5 mm and 2 mm, and preferably about 1 mm;
C. forming, at the outlet of said capillary tube, a drop of said solution, said drop being electrically charged so as to bring about its destabilization in the form of a cone;
D. ejecting, from said cone, a liquid cylinder toward an electrically conductive target, which is electrically earthed;
E. evaporating said solvent during the ejecting of said liquid cylinder, resulting in a vortex instability generating solid nanofibers of the material;
F. collecting, on a face of said target oriented toward said cylinder, said solid nanofibers so as to form a mat of nanofibers forming a fibrous fabric, said target being, prior to step B, covered with a non-stick coating;
said process being characterized in that it also comprises, at the end of step F, an additional step G of wetting said fibrous fabric with a wetting liquid so as to form a wetted membrane, and
in that it comprises a step H of immersing the wetted membrane thus obtained in a fluid which is immiscible with the wetting liquid, so as to create an A/B interface between the wetting liquid and said immiscible fluid and thus to form the composite membrane as claimed in the invention.

10. The process as claimed in claim 9, wherein said non-stick coating is a parchment paper.

11. The process as claimed in claim 9, wherein:
said face of the target is a flat face located at a distance L from the outlet of said capillary tube which is between 5 cm and 15 cm, and
said capillary tube is subjected to an electrical voltage U of between 10 kV and 15 kV.

12. The process as claimed in claim 11, wherein:
said flat surface of the target is located at a distance L from the outlet of said capillary tube which is about 10 cm, and
said capillary tube is subjected to an electrical voltage U of about 12 kV.

13. The process as claimed in claim 9, wherein said constituent material of the fabric is a polymer material chosen from the group consisting of the following polymers:
polyacrylonitrile (PAN),
polyvinylidene fluoride-co-hexafluoropropylene (PVDF-HFP),
polyvinylpyrrolidone (PVP),
polyvinyl alcohol (PVA),
polyethylene oxide (PEO), and
polyvinylidene fluoride (PVDF).

14. The process as claimed in claim 9, wherein said constituent material of the fabric is a polymer-inorganic network hybrid material, wherein the inorganic network may be, for example, SiO₂ (silica), TiO₂ (titanium dioxide), Fe₂O₃(iron oxide), in the form of an amorphous network or of crystallized nanoparticles.

15. The process as claimed in claim 9, wherein said A/B interface is an oil/air interface, an oil/water interface, or a glycerol/air interface, or an interface of water with surfactant/air.
